(19) United States
(12) Patent Application Publication
(10) Pub. No.: US 2014/0057437 A1
(43) Pub. Date: Feb. 27, 2014

(54) RINSING AGENT FOR LITHOGRAPHY, METHOD FOR FORMING A RESIST PATTERN, AND METHOD FOR PRODUCING A SEMICONDUCTOR DEVICE

(71) Applicant: FUJITSU LIMITED, Kawasaki-shi (JP)

(72) Inventors: Miwa KOZAWA, Atsugi (JP); Junichi KON, Isehara (JP); Koji NOZAKI, Atsugi (JP)

(21) Appl. No.: 13/928,954

(22) Filed: Jun. 27, 2013

(30) Foreign Application Priority Data
Aug. 27, 2012 (JP) 2012-186452

(51) Int. Cl. G03F 7/42; H01L 21/308

(52) U.S. Cl. CPC G03F 7/422; H01L 21/308
USPC 438/689; 510/176; 430/432

(57) ABSTRACT

To provide a rinsing agent for lithography, which contains C6-C8 straight-chain alkanediol, and water.

### CROSS-REFERENCE TO RELATED APPLICATIONS

This application is based upon and claims the benefit of priority of the prior Japanese Patent Application No. 2012-186452, filed on Aug. 27, 2012, the entire contents of which are incorporated herein by reference.

### FIELD

The embodiments discussed herein relate to a rinsing agent for lithography, a method for forming a resist pattern, and a method for producing a semiconductor device.

### BACKGROUND

There have been demands for formation of fine patterns in semiconductor devices, such as of large scale integration (LSI), as integration degrees thereof have been improved. Currently, the smallest pattern size reaches to the region of 100 nm or smaller.

Formations of such fine patterns in semiconductor devices have been realized by shortening wavelength of light from a light source of exposure devices. Currently, formations of fine patterns have been performed by a liquid immersion lithography, in which exposure is performed through water with a light source that emits argon fluoride (ArF) excimer laser light having a wavelength of 193 nm. As for further down-sizing, studies have been conducted to achieve pattern dissolution in the size of 30 nm or smaller, by electron beam exposure using electron beams, or extreme ultraviolet ray (EUV) exposure using soft X-rays having wavelength of 13.5 nm.

Such down-sizing of a resist pattern has caused a problem that a fine pattern is collapsed due to surface tension when a rinsing agent is dried in developing of the resist pattern. When a resist pattern size is 100 nm or smaller and an aspect ratio, which is a ratio of a resist film thickness to the resist pattern size, is greater than 2, an influence of the surface tension becomes large.

Moreover, a problem associating with such fine resist pattern having the size of 100 nm or smaller is that irregularities of a width of the resist pattern (LWR: line width roughness) increases, which adversely affects a performance of a resulting device.

To solve these problems, optimizations of exposing devices and resist materials have been studied, but improvements of exposing devices and resist materials need notable cost and time. Accordingly, a sufficient result has not been attained.

Therefore, various countermeasures in a process have been studied.

For example, for the purpose of preventing collapse of a resist pattern, disclosed as a rinsing agent used in rinsing after developing is a rinsing agent containing a fluoro compound that is water-soluble, or is soluble to an alcohol-based solvent (see, for example, Japanese Patent Application Laid-Open (JP-A) No. 2005-309260). Moreover, disclosed is a method for forming a resist pattern using a rinsing agent containing a specific compound (see, for example, JP-A Nos. 2012-42531, and 2005-294354).

For the purpose of improving LWR, disclosed is a method where an organic coating material to which an acidic low molecular compound containing a carboxyl group or the like is applied to a resist pattern, which has been developed, and a resultant is pealed to make the resist pattern fine, as well as improving the LWR (see, for example, JP-A No. 2010-49247).

However, these disclosed techniques cannot improve both collapse of a resist pattern and LWR, which are problems in fine resist patterns.

Therefore, as a means for improving both collapse of a resist pattern and LWR, disclosed is a cleansing agent (rinsing agent) for lithography, which is formed of an aqueous solution containing: a nitrogen-containing cationic surfactant or a nitrogen-containing amphoteric surfactant or both thereof; and an anionic surfactant (see, for example, JP-A No. 2007-213013).

However, this disclosed technique realizes to improve LWR with rinsing to remove a surface of a resist pattern, and therefore it is difficult to control the resist pattern size to the intended range. Therefore, it cannot be said that this method is a sufficient method to prevent the aforementioned problems.

Moreover, disclosed by the present inventors is a resist pattern improving material, which contains C4-C11 straight-chain alkanediol, and improves LWR of a resist pattern (see, for example, JP-A No. 2012-108445).

Moreover, as a means for preventing collapse of a resist pattern, disclosed is a rinsing agent, which contains, in water, one or more selected from the group containing C1-C18 hydrocarbon group-containing monoalcohol, C2-C10 hydrocarbon group-containing polyhydric alcohol, an alkylene oxide adduct of the monoalcohol or the polyhydric alcohol, an alkylene oxide adduct of a phenol compound that may have a substituent (provided that a number of carbon atoms in the phenol compound that may have a substituent is 6 to 27), and an alkylene oxide adduct of amine, where the amine is a monovalent to tetravalent amine having a C1-C10 hydrocarbon group, and a primary or secondary amino group (see, for example, JP-A No. 2003-107744).

Although a few compounds are listed as the C2-C10 hydrocarbon group-containing polyhydric alcohol, the compound to which an effect as a rinsing agent is concretely confirmed is only glycerin. Other C2-C10 hydrocarbon group-containing polyhydric alcohols are not confirmed at all to have an effect as a rinsing agent. Moreover, an effect of improving LWR is not disclosed.

Accordingly, there are currently needs for a rinsing agent for lithography, which can prevent collapse of a resist pattern during rinsing after development performed for forming a resist pattern, and can improve LWR without changing a size of the resist pattern more than necessary, and a method for forming a resist pattern and a method for producing a semiconductor device, which can prevent collapse of a resist pattern during rinsing after development performed for forming a resist pattern, and can improve LWR without changing a size of the resist pattern more than necessary.

### SUMMARY

The disclosed rinsing agent for lithography contains C6-C8 straight-chain alkanediol, and water.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A is a schematic diagram for explaining one example of the disclosed method for producing a semiconductor device, and illustrates a state where an interlayer insulating film is formed on a silicon substrate.

FIG. 1B is a schematic diagram for explaining one example of the disclosed method for producing a semiconductor device, and illustrates a state where a titanium film is formed on the interlayer insulating film illustrated in FIG. 1A.

FIG. 1C is a schematic diagram for explaining one example of the disclosed method for producing a semiconductor device, and illustrates a state where a resist film is formed on the titanium film, and a hole pattern is formed in the titanium film.

FIG. 1D is a schematic diagram for explaining one example of the disclosed method for producing a semiconductor device, and illustrates a state where the hole pattern is also formed in the interlayer insulating film.

FIG. 1E is a schematic diagram for explaining one example of the disclosed method for producing a semiconductor device, and illustrates a state where a Cu film is formed on the interlayer insulating film in which the hole pattern has been formed.

FIG. 1F is a schematic diagram for explaining one example of the disclosed method for producing a semiconductor device, and illustrates the state where the Cu deposited on the area of the interlayer insulating film where the hole pattern has not been formed was removed.

FIG. 1G is a schematic diagram for explaining one example of the disclosed method for producing a semiconductor device, and illustrates the state where an interlayer insulating film is formed on a Cu plug, which has been formed in the hole pattern, and on the interlayer insulating film.

FIG. 1H is a schematic diagram for explaining one example of the disclosed method for producing a semiconductor device, and illustrates the state where a hole pattern is formed in the interlayer insulating film serving as a surface layer, and a Cu plug is formed.

FIG. 1I is a schematic diagram for explaining one example of the disclosed method for producing a semiconductor device, and illustrates the state where a wiring of three-layer structure is formed.

### DESCRIPTION OF EMBODIMENTS

### (Rinsing Agent for Lithography)

The disclosed rinsing agent for lithography (may be referred to as a “rinsing agent” hereinafter) contains at least C6-C8 straight-chain alkanediol, and water, and may further contain other components, if necessary.

### <Straight-Chain Alkanediol>

The straight-chain alkanediol is appropriately selected depending on the intended purpose without any limitation, provided that it is C6-C8 straight-chain alkanediol. The straight-chain alkanediol is preferably 1,2-hexanediol, 1,2-heptanediol, 1,2-octanediol or 1,8-octanediol or any combination thereof, because an effect of preventing collapse of a resist pattern is high and irregularities in the resist pattern width (LWR: line width roughness) can be improved (reduced).

The straight-chain alkanediol may be used alone, or in combination.

An amount of the straight-chain alkanediol in the rinsing agent is appropriately selected depending on the intended purpose without any limitation, but the amount thereof is preferably 0.1 parts by mass or greater relative to 100 parts by mass of the water, more preferably 0.2 parts by mass or greater, further preferably 0.2 parts by mass or greater as well as equal to or greater than the upper limit of the amount thereof dissolved in water of 20° C. (i.e., solubility to water of 20° C.), yet further preferably 0.2 parts by mass to 1.5 parts by mass, and particularly preferably 0.2 parts by mass to 0.8 parts by mass. When the amount thereof is smaller than 0.1 parts by mass, an effect of preventing collapse of a resist pattern, and an effect of improving LWR may not be attained at all. When the amount thereof is greater than the upper limit of the amount dissolved in water of 20° C. (solubility), the straight-chain alkanediol, which has not been dissolved, may be present in the rinsing agent. In this case, the rinsing agent becomes an ununiform liquid, and therefore an effect of preventing collapse of a resist pattern, and an effect of improving LWR of a resist pattern may not be attained at all. In addition, the straight-chain alkanediol may be deposited as a residue on a surface of a resist pattern or between the resist pattern after rinsing. When the amount thereof is within the aforementioned particularly preferable range, it is advantageous because collapse of a resist pattern is more effectively prevented, and LWR is improved even further.

### <Water>

The water is appropriately selected depending on the intended purpose without any limitation, but the water is preferably pure water (deionized water).

An amount of the water in the rinsing agent is appropriately selected depending on the intended purpose without any limitation, but the amount thereof is preferably 80 parts by mass or greater relative to 100 parts by mass of the rinsing agent in view of easiness in use as the rinsing agent. When the amount thereof is smaller than 80 parts by mass, a viscosity of the rinsing agent increases, which may cause contamination inside a rinsing device, or leave a residue of the rinsing agent.

### <Other Component>

Other components are appropriately selected depending on the intended purpose without any limitation, provided that they do not adversely affect the disclosed effects, and examples thereof include a water-soluble polymer, a surfactant, an organic solvent, and various conventional additives.

These components are effective for adjustment of a surface tension to a resist pattern during rinsing using the rinsing agent, and for an improvement of affinity.

### —Water-Soluble Polymer—

The water-soluble polymer is appropriately selected depending on the intended purpose without any limitation, and examples thereof include polyvinyl alcohol, polyvinyl acetal, polyvinyl acetate, polyacrylic acid, polyvinyl pyrrolidone, polethylene imine, polyethylene oxide, a styrene-maleic acid copolymer, polyvinyl amine, polyallyl amine, an oxazoline group-containing water-soluble resin, a water-soluble melamine resin, a water-soluble urea resin, an alkyd resin, a sulfone amide resin, cellulose, tannin, and a resin containing any of the aforementioned resins at least in part thereof. These may be used alone, or in combination.

In view of safety, the water-soluble polymer is preferably polyvinyl alcohol, polyvinyl acetal, polyvinyl acetate, polyvinyl pyrrolidone, or a resin containing any of the aforementioned resins at least in part thereof, or any combination thereof.

The water-solubility of the water-soluble polymer is appropriately selected depending on the intended purpose without any limitation. For example, such water solubility is preferable that 0.1 g or more of the water-soluble polymer is dissolved in 100 g of water at 25° C.

An amount of the water-soluble polymer in the rinsing agent is appropriately selected depending on the intended purpose without any limitation, but the amount thereof is preferably 10 parts by mass or smaller, more preferably 4 parts by mass or smaller, relative to 100 parts by mass of the water. When the amount of the water-soluble polymer is greater than 10 parts by mass, a film residue may be remained on a resist pattern, which may cause a notable change in a size of the resist pattern after developing and rinsing. When the amount thereof is within the aforementioned more preferable range, it is advantageous because an influence of the water-soluble polymer to a size of a resist pattern is not noticeable, collapse of the resist pattern is prevented, and uniformity of a width of the resist pattern is improved within the intended resist pattern size. The lower limit of the amount thereof is appropriately selected depending on the intended purpose without any limitation, but the lower limit is preferably 0.001 parts by mass or greater.

### —Surfactant—

The surfactant is appropriately selected depending on the intended purpose without any limitation, and examples thereof include a nonionic surfactant, a cationic surfactant, an anionic surfactant, and an amphoteric surfactant. These may be used alone, or in combination. Among them, the nonionic surfactant and the cationic surfactant are preferable, as these surfactants do not contain a metal ion, such as a sodium salt, and a potassium salt.

The nonionic surfactant is appropriately selected depending on the intended purpose without any limitation, and examples thereof include a polyoxyethylene-polyoxypropylene condensate compound, a polyoxyalkylene alkyl ether compound, a polyoxyethylene alkyl ether compound, a polyoxyethylene derivative compound, a sorbitan fatty acid ester compound, a glycerin fatty acid ester compound, a primary alcohol ethoxylate compound, a phenol ethoxylate compound, a nonylphenol ethoxylate-based compound, an octylphenol ethoxylate-based compound, a lauryl alcohol ethoxylate-based compound, an oleyl alcohol ethoxylate-based compound, a fatty acid ester-based compound, an amide-based compound, and a natural alcohol-based compound, an ethylene diamine-based compound, and a secondary alcohol ethoxylate-based compound.

The cationic surfactant is appropriately selected depending on the intended purpose without any limitation, and examples thereof include cetyl methyl ammonium chloride, stearyl methyl ammonium chloride, cetyl trimethyl ammonium chloride, stearyl trimethyl ammonium chloride, distearyl dimethyl ammonium chloride, stearyl dimethyl benzyl ammonium chloride, dodecyl methyl ammonium chloride, dodecyl trimethyl ammonium chloride, benzyl methyl ammonium chloride, benzyl trimethyl ammonium chloride, and benzalkonium chloride.

An amount of the surfactant in the rinsing agent is appropriately selected depending on the intended purpose without any limitation, but the amount thereof is preferably 0.1 parts by mass or greater, more preferably 0.1 parts by mass to 1.5 parts by mass, relative to 100 parts by mass of the water. When the amount of the surfactant is smaller than 0.1 parts by mass, an effect of preventing collapse of a resist pattern, and an effect of improving LWR may not be attained at all. When the amount thereof is within the aforementioned more preferable range, it is advantageous because collapse of a resist pattern is more effectively prevented, and LWR is improved even further.

A sum of the amount of the C6-C8 straight-chain alkanediol and the amount of the surfactant is appropriately selected depending on the intended purpose without any limitation, but the sum is preferably 0.2 parts by mass or greater, more preferably 0.2 parts by mass to 1.5 parts by mass, relative to 100 parts by mass of the water. When the sum is smaller than 0.2 parts by mass, an effect of preventing collapse of a resist pattern, and an effect of improving LWR may not be attained at all. When the sum is within the aforementioned more preferable range, it is advantageous because collapse of a resist pattern is more effectively prevented, and LWR is improved even further.

In the case where the sum of the amount of the C6-C8 straight-chain alkanediol and the amount of the surfactant is within the aforementioned preferable range or more preferable range, the surfactant is preferably the cationic surfactant, and more preferably benzalkonium chloride, as collapse of a resist pattern is more effectively prevented, and LWR is improved even further.

### —Organic Solvent—

The organic solvent is appropriately selected depending on the intended purpose without any limitation, and examples thereof include an alcohol-based organic solvent, a straight chain ester-based organic solvent, a cyclic ester-based organic solvent, a ketone-based organic solvent, a straight chain ether-based organic solvent, and a cyclic ether-based organic solvent.

Examples of the alcohol-based organic solvent include ethanol, and isopropyl alcohol. Examples of the straight chain ester-based organic solvent include 2-hydroxyethyl acetate. Examples of the cyclic ester-based organic solvent include γ-butyrolactone. Examples of the ketone-based organic solvent include acetone. Examples of the straight chain ether-based organic solvent include ethylene glycol monomethyl ether, and propylene glycol monomethyl ether. Examples of the cyclic ether-based organic solvent include tetrahydrofuran. These may be used alone, or in combination.

Examples of the various additives include a quencher, such as an amine quencher, an amide quencher, and ammonium chloride. These may be used alone, or in combination.

An amount of the organic solvent, or various conventional additives is not particularly limited, and is appropriately selected depending on types or amounts of the C6-C8 straight-chain alkanediol, the water, and the water-soluble polymer.

The form of the rinsing agent is appropriately selected depending on the intended purpose without any limitation, and examples thereof include an aqueous solution, a colloid solution, and an emulsion. Among them, the aqueous solution is preferable in view of easiness in handling.

### <Use and the Like>

The rinsing agent for lithography can be used as a rinsing agent following developing performed on a resist film with a developing solution, such as an alkali developing solution, after performing exposing on the resist film, which is formed on a processing surface by applying a resist material onto the processing surface.

One example of a method for using the rinsing agent is explained below.

First, a resist film is formed on a processing surface. Subsequently, exposing is performed on the formed resist film. The exposing may include heating depending on a type of a resist.

Next, developing is performed on the resist film, to which the exposing has been performed, using an alkali developing solution. As for the alkali developing solution, for example, a 2.38% by mass tetramethyl ammonium hydroxide (TMAH) aqueous solution is used, and the developing is carried out by spinning, scanning, or dipping.

Next, before the developing solution applied to the resist film is dried, namely in the state where the developing solution is located on the resist film, rinsing is performed using the rinsing agent. The rinsing is performed on the resist pattern, on which the developing solution has not been dried, with the rinsing agent, for example, by spinning, scanning, or dipping. During this process, surface tension caused when the rinsing agent is dried is reduced due to affinity between the rinsing agent and the resist pattern, and therefore it is possible to prevent collapse of a resist pattern. Moreover, this affinity reduces irregularities of side surfaces of the resist pattern, and therefore it is possible to form a resist pattern whose LWR has been improved.

As a result of that collapse of a resist pattern, which occurs during developing of the resist pattern, is prevented by the rinsing agent, the intended fine pattern can be formed.

Moreover, use of the rinsing agent reduces irregularities on side surfaces of the resist pattern, and improves uniformity of a line width of the resist pattern.

As described above, by using the rinsing agent for lithography, the resist pattern, which is highly precise and highly accurate compared to the conventional art, can be formed.

### —Material of Resist Pattern—

A material of the resist pattern (the resist pattern to which rinsing is performed with the rinsing agent for lithography) is appropriately selected from conventional resist materials depending on the intended purpose without any limitation, and the material of the resist pattern may be a negative material, or a positive material. Examples of the material of the resist pattern include resist materials that can be patterned by g-line, i-line, KrF excimer laser light, ArF excimer laser light, F₂ excimer laser light, an electron beam and the like, such as a g-line resist, an i-line resist, a KrF resist, an ArF resist, a F₂ resist, an EUV resist, and an electron beam resist. There may be of chemically amplified, or of chemically non-amplified. Specific examples of the material of the resist pattern include a novolak-based resist, a polyhydroxystyrene (PHS)-based resist, an acryl-based resist, a cycloolefin-maleic acid anhydride (COMA)-based resist, a cycloolefin-based resist, and a hybrid (alicyclic acryl-COMA copolymer) resist. These may be fluorine-modified.

Among them, preferred are either or both of a resist containing an acryl-based resin, and a resist containing a hydroxystyrene resin, as finer patterning can be realized, and through-put can be improved.

The method for forming a resist pattern, a size of the resist pattern, and a film thickness of the resist pattern are appropriately selected depending on the intended purpose without any limitation. For example, the film thickness can be appropriately determined depending on a processing surface, which is a subject to be processed, and etching conditions, and is typically about 20 nm to about 500 nm.

The rinsing agent can be suitably used for a resist pattern having L/S (line and space) of 100 nm or smaller. The rinsing agent for lithography can be suitably used for preventing collapse of a fine pattern, reducing irregularities of side surfaces of a resist pattern to improve the LWR, and forming a very fine resist pattern extending the exposure limit. Moreover, the rinsing agent for lithography can be particularly suitably used in the method for forming a resist pattern, and method for producing a semiconductor device, which will be described below.

### (Method for Forming Resist Pattern)

The disclosed method for forming a resist pattern contains developing (a developing step), and rinsing (a rinsing step), preferably further contains heating (a heating step), and secondary rinsing (a second rinsing step), and may further contain other steps, if necessary.

### <Developing Step>

The developing step is appropriately selected depending on the intended purpose without any limitation, provided that the developing step is developing a resist film, which is formed on a processing surface and subjected to exposing, with a developing solution.

The resist film can be formed, for example, by applying the material of the resist pattern onto a processing surface. Examples of the processing surface include a surface of a semiconductor base. Examples of the semiconductor base include a substrate, such as silicon wafer, and various oxide films. Examples of the application method include spin coating.

The exposing is appropriately selected depending on a sensitive wavelength of the material of the resist pattern to be exposed, without any limitation. Specific examples of the activation energy used for the exposing include broad-band ultraviolet light emitted from a high pressure mercury lamp or a low pressure mercury lamp, g-line (wavelength: 436 nm), i-line (wavelength: 365 nm), KrF excimer laser light (wavelength: 248 nm), ArF excimer laser light (wavelength: 193 nm), F₂ excimer laser light (wavelength: 157 nm), EUV light (wavelength: soft X-ray region of 5 nm to 15 nm), electron beams, and X-rays. Among them, use of ArF excimer laser light, F₂ excimer laser light, EUV light, electron beams, or X-rays for exposure causes notable collapse of a fine pattern, or LWR of the fine pattern, but the disclosed method for forming a resist pattern has a high effect of preventing the collapse of the fine pattern, or improving LWR of the fine pattern.

Heating may be performed after applying the material of the resist pattern, and/or after exposing the resist film to light, depending on a type of the material of the resist pattern. The heating is performed promptly after applying or exposing, for example, by an oven, or a hot plate. Conditions of the heating are appropriately selected depending on the intended purpose without any limitation.

The developing solution is appropriately selected depending on the intended purpose without any limitation, and examples thereof include an alkali developing solution. Examples of the alkali developing solution include a 2.38% by mass tetramethyl ammonium hydroxide (TMAH) aqueous solution.

As a result of the developing step, a resist pattern is formed in the resist film, to which the exposing has been performed.

### <Rinsing Step>

The rinsing step is appropriately selected depending on the intended purpose without any limitation, provided that the rinsing step is following the developing step, rinsing the resist film with a rinsing agent for lithography, and examples thereof include a step in which the rinsing agent for lithography is applied to the resist pattern, which has been developed with an alkali developing solution, by spin coating, scanning, or dipping. Specifically, the rinsing step is performed, for example, by following the developing with an alkali developing solution, applying the rinsing agent to the resist film (resist pattern) dropwise, or by dipping using the similar device to the device used for developing with the alkali developing solution before the alkali developing solution applied to the resist film is dried, i.e., in the state where the alkali developing solution is located on the resist film, to replace the alkali developing solution with the rinsing agent, followed by drying.

Conditions of the rinsing step are appropriately selected depending on the intended purpose without any limitation, but a processing time thereof is preferably 1 second to 10 minutes, more preferably 1 second to 180 seconds.

### <Heating Step>

The heating step is appropriately selected depending on the intended purpose without any limitation, provided that the heating step is heating following the rinsing step. Examples of the heating step include a method for heating the resist pattern by an oven or a hot plate. By heating the resist pattern, affinity between the rinsing agent for lithography and the resist pattern are improved, and particularly an effect of improving LWR is enhanced.

Conditions of the heating are appropriately selected depending on the intended purpose without any limitation, as long as the resist pattern is not be softened by the heating. For example, heating temperature may be constant, or varied. In the case where the heating temperature is constant, the heating temperature is preferably 40° C. to 150° C., more preferably 60° C. to 120° C. Moreover, the heating time is preferably 10 seconds to 5 minutes, more preferably 30 seconds to 100 seconds. Further, after the heating step, a second rinsing step may be carried out using pure water.

### <Second Rinsing Step>

The second rinsing step is appropriately selected depending on the intended purpose without any limitation, provided that the second rinsing step is performing second rinse with pure water after the rinsing.

The second rinsing step is preferably performed before the rinsing agent for lithography used in the rinsing step is dried.

In the case where the method for forming a resist pattern includes the heating step, the second rinsing step may be performed before or after the heating step.

Conditions of the second rinsing step are appropriately selected depending on the intended purpose without any limitation, but a processing time of the second rinsing is preferably 1 second to 10 minutes, more preferably 1 second to 180 seconds.

By performing the second rinsing step, in some cases, a possibility that the rinsing agent for lithography is deposited on a processing surface, such as a front or back surface of a silicon wafer is reduced, and edges of a resist pattern become clear, to thereby improve LWR.

The method for forming a resist pattern can be used for formation of various resist pattern, but the method for forming a resist pattern is particularly suitable for formation of a line and space pattern, and an isolated pattern (e.g., a gate pattern), with which problems of collapse of a resist pattern, and LWR are notable.

A resist pattern formed by the method for forming a resist pattern can be used, for example, as a mask pattern, or a reticle pattern.

The method for forming a resist pattern can be suitably used in productions of metal plugs, various wirings, magnetic heads, liquid crystal displays (LCD), plasma display panels (PDP), functional parts such as a surface acoustic wave (SAW) filter, optical parts used for connections of optical wiring, precision parts such as a microactuator, and semiconductor devices. Furthermore, the disclosed method for forming the resist pattern is suitably used in the method for producing a semiconductor device, which will be explained later.

### (Method for Producing Semiconductor Device)

The disclosed method for producing a semiconductor device contains at least developing (a developing step), rinsing (a rinsing step), and patterning (a patterning step), preferably further contains heating (a heating step), and secondary rinsing (a second rinsing step), and may further contain other steps, if necessary.

### <Developing Step>

The developing step is appropriately selected depending on the intended purpose without any limitation, provided that the developing step is developing a resist film, which has been formed on a processing surface and subjected to exposing, with a developing solution, and examples thereof include the developing step explained in the disclosed method for forming a resist pattern.

### <Rinsing Step>

The rinsing step is appropriately selected depending on the intended purpose without any limitation, provided that the rinsing step is following the developing step, rinsing the resist film with the disclosed rinsing agent for lithography, and examples thereof include the rinsing step described in the disclosed method for forming a resist pattern.

### <Patterning Step>

The patterning step is appropriately selected depending on the intended purpose without any limitation, provided that the patterning step is after the rinsing step, etching the processing surface using the formed resist pattern as a mask to pattern the processing surface.

A method of the etching is appropriately selected from methods know in the art depending on the intended purpose without any limitation, but the method of the etching is preferably dry etching. Conditions of the etching are appropriately selected depending on the intended purpose without any limitation.

### <Heating Step>

The heating step is appropriately selected depending on the intended purpose without any limitation, provided that the heating step is heating following the rinsing step, and examples of the heating step is the heating step described in the method for forming a resist pattern.

The heating step is preferably performed following the rinsing step, but before the patterning step.

### <Second Rinsing Step>

The second rinsing step is appropriately selected depending on the intended purpose without any limitation, provided that the second rinsing step is performing second rinse with pure water after the rinsing, and examples of the second rinsing step include the second rinsing step described in the disclosed method for forming a resist pattern.

The second rinsing step is preferably performed after the rinsing step, but before the patterning step.

The disclosed method for producing a semiconductor device can effectively produce various semiconductor devices, such as a flash memory, a dynamic random access memory (DRAM), and ferroelectric RAM (FRAM).

The disclosed rinsing agent for lithography can solve the aforementioned various problems in the art, can achieve the aforementioned object, and can provide a rinsing agent for lithography, which can prevent collapse of a resist pattern during rinsing after developing performed for formation of the resist pattern, and can improve LWR without changing a size of the resist pattern more than necessary.

The disclosed method for forming a resist pattern can solve the aforementioned various problems in the art, can achieve the aforementioned object, and can provide a method for forming a resist pattern, which can prevent collapse of a resist pattern during rinsing after developing performed for formation of the resist pattern, and can improve LWR without changing a size of the resist pattern more than necessary.

The disclosed method for producing a semiconductor device can solve the aforementioned various problems in the art, can achieve the aforementioned object, and can provide a method for producing a semiconductor device, which can prevent collapse of a resist pattern during rinsing after developing performed for formation of the resist pattern, and can improve LWR without changing a size of the resist pattern more than necessary.

### EXAMPLES

The disclosed rinsing agent and the disclosed method for forming a resist pattern are more specifically explained through Examples hereinafter, but Examples shall not construed as to limit the disclosed rinsing agent, and the disclosed method for forming a resist pattern.

### Example 1

### Preparation of Rinsing Agent for Lithography

The following (A) straight-chain alkanediol, (B) additives, (C) water-soluble polymers, and (D) solvents were provided.

### (A) Straight-Chain Alkanediol

A-1: 1,2-heptanediol (manufactured by Tokyo Chemical Industry Co., Ltd.)
A-2: 1,2-hexanediol (manufactured by Tokyo Chemical Industry Co., Ltd.)
A-3: 1,2-octanediol (manufactured by Tokyo Chemical Industry Co., Ltd.)
A-4: 1,8-octanediol (manufactured by Tokyo Chemical Industry Co., Ltd.)

### (B) Additive

B-1: hexyl dimethylol propionate-based surfactant (surfactant, manufactured by Nikko Chemicals Co., Ltd.)
B-2: polyoxyethylene lauryl ether-based surfactant (surfactant, manufactured by Kao Corporation)
B-3: N,N,N′,N′-tetramethyl ethylene diamine (manufactured by Kanto Chemical Co., Inc.)
B-4: benzalkonium chloride (surfactant, manufactured by Wako Pure Chemical Industries, Ltd.)

### (C) Water-Soluble Polymer

C-1: polyvinyl alcohol (PVA-205C, manufactured by Kuraray Co., Ltd.)
C-2: polyvinyl pyrrolidone (manufactured by Kanto Chemical Co., Inc.) (D) Solvent

### D-1: Water

### D-2: Isopropyl Alcohol

The rinsing agent for lithography Nos. 1 to 24 each having respective composition depicted in Table 1 were prepared using the above-listed (A) to (D).

In Table 1, the numerical values in the brackets represent parts by mass.

TABLE 1

| Rinsing | | | | |
|---|---|---|---|---|
| agent No. | (A) | (B) | (C) | (D) |
| 1 | — | — | — | D-1 (100) |
| 2 | A-1 (0.5) | — | — | D-1 (100) |
| 3 | A-2 (0.5) | — | — | D-1 (100) |
| 4 | A-3 (0.3) | — | — | D-1 (100) |
| 5 | A-4 (0.5) | — | — | D-1 (100) |
| 6 | — | B-1 (0.5) | — | D-1 (100) |
| 7 | — | B-2 (0.5) | — | D-1 (100) |
| 8 | — | B-3 (0.5) | — | D-1 (100) |
| 9 | — | B-4 (0.5) | — | D-1 (100) |
| 10 | A-3 (0.1) | — | — | D-1 (100) |
| 11 | A-3 (0.2) | — | — | D-1 (100) |
| 12 | A-3 (0.5) | — | — | D-1 (100) |
| 13 | A-3 (0.3) | — | C-1 (1) | D-1 (100) |
| 14 | A-3 (0.3) | — | C-2 (1) | D-1 (100) |
| 15 | A-3 (0.3) | — | — | D-1 (98), D-2 (2) |
| 16 | A-3 (0.1) | B-2 (0.5) | — | D-1 (100) |
| 17 | A-3 (0.1) | B-4 (0.1) | — | D-1 (100) |
| 18 | A-3 (0.1) | B-4 (0.5) | — | D-1 (100) |
| 19 | A-3 (0.1) | B-4 (1.0) | — | D-1 (100) |
| 20 | A-4 (0.1) | — | — | D-1 (100) |
| 21 | A-4 (0.2) | — | — | D-1 (100) |
| 22 | A-4 (1.0) | — | — | D-1 (100) |
| 23 | A-4 (0.5) | — | C-1 (1) | D-1 (100) |
| 24 | A-4 (0.5) | — | C-2 (1) | D-1 (100) |

### <Formation of Resist Pattern>

A resist (chemically-amplified positive resist) material used for evaluation was prepared by mixing the following substances.

### [Formulation of Resist Material]

| | | |
|---|---|---|
| Resin: 30 mol % t-butoxycarbonylated (t-Boc) | 100 | parts by mass |
| poly(p-hydroxy) styrene (manufactured by | | |
| Maruzen Petrochemical Co., Ltd.) | | |
| Photo acid generator: triphenyl sulfonium | 8 | parts by mass |
| nonafluorobutane sulfonate (manufactured by | | |
| Midori Kagaku Co., Ltd.) | | |
| Additive: hexyl amine (manufactured by Kanto | 0.5 | parts by mass |
| Chemical Co., Inc.) | | |
| Solvent: propylene glycol monomethyl ether | 700 | parts by mass |
| acetate (manufactured by Kanto Chemical Co., | | |
| Inc.) | | |

The resist material above was applied onto a silicon substrate by spin coating to give a film thickness of 250 nm, and the applied resist material was baked at 120° C. for 60 seconds. Subsequently, the substrate was exposed to light by means of an electron beam exposure device at the accelerated voltage of 50 keV to write a set of 101 line and space patterns (100 lines of a resist line pattern) each having a width of 100 nm. Subsequently, the resulting resist material was baked at 110° C. for 60 seconds.

Next, paddle development was performed for 30 seconds using a 2.38% by mass tetramethyl ammonium hydroxide aqueous solution (developing solution). Before the resist film was dried (in the state where the developing solution was located on the resist film), each of the rinsing agents of Table 1 was applied onto the resist film dropwise, to replace the developing solution with the rinsing agent, and then the rinsing agent was shaken off. Finally, drying was performed.

### <Evaluation of Rinsing Agent for Lithography>

Next, the resist pattern obtained through the aforementioned process was observed under a scanning electron microscope (SEM), to determine a state of collapse of the resist pattern (resist line pattern), variation in a width of the resist pattern (resist line pattern), and a line width of the obtained resist line pattern. The results are presented in Table 2.

The effect of preventing collapse of the resist pattern was evaluated in the following manner. The number of the resist line patterns, which were collapsed, out of the 100 resist line patterns were counted, and presented according to the following criteria based on the counted number.

### [Criteria]

A: The number of the resist patterns collapsed was less than 10.
B: The number of the resist patterns collapsed was 10 or more but less than 30.
C: The number of the resist patterns collapsed was 30 or more but less than 50.
D: The number of the resist patterns collapsed was more than 50.

A line width (“size after processing” in Tables 2 to 4) of the obtained resist pattern, an amount of change in the resist pattern width (“amount of change” in Tables 2 to 4), variation in the resist pattern width (“LWR” in Tables 2 to 4), and LWR improvement rate (%) were determined.

LWR was determined by observing line width of the resist pattern in the region of the length of about 720 nm under a critical dimension SEM to measure the line width at 25 points, determined the standard deviation (σ) of the variations in the line width based on the average value of the measured values from the 25 points, and tripling the standard deviation (σ). A ratio of the improved amount of the LWR value after the processing to the LWR value before processing (the case where the rinsing agent No. 1 was used) was determined based on the following formula, and the obtained value was defined as “LWR improvement rate (%).”

LWR improvement rate (%)=[(LWR of unprocessed pattern−LWR after processing)/(LWR of unprocessed pattern)]×100

TABLE 2

| | Effect of | | | | |
|---|---|---|---|---|---|
| | preventing | Size after | Amount of | | LWR |
| Rinsing | collapse of | processing* | change | LWR | improvement |
| agent No. | resist pattern | (nm) | (nm) | (nm) | rate (%) |
| 1 | D | 97 | — | 11.1 | — |
| 2 | C | 96 | −1 | 9.1 | 18 |
| 3 | C | 96 | −1 | 9.0 | 19 |
| 4 | A | 96 | −1 | 7.6 | 32 |
| 5 | A | 97 | 0 | 7.7 | 31 |
| 6 | D | 90 | −7 | 11.9 | −7 |
| 7 | C | 89 | −8 | 12.0 | −8 |
| 8 | C | 90 | −7 | 12.4 | −12 |
| 9 | B | 96 | −1 | 10.1 | 9 |
| 10 | C | 97 | 0 | 8.3 | 25 |
| 11 | B | 97 | 0 | 7.8 | 30 |
| 12 | A | 96 | −1 | 8.0 | 28 |
| 13 | A | 100 | 3 | 6.8 | 39 |
| 14 | A | 99 | 2 | 8.1 | 27 |
| 15 | A | 96 | −1 | 7.9 | 29 |
| 16 | C | 90 | −7 | 11.8 | −6 |
| 17 | B | 96 | −1 | 8.1 | 27 |
| 18 | A | 96 | −1 | 7.6 | 32 |
| 19 | A | 97 | 0 | 7.9 | 29 |
| 20 | C | 97 | 0 | 8.8 | 21 |
| 21 | B | 97 | 0 | 7.7 | 31 |
| 22 | B | 96 | −1 | 7.6 | 32 |
| 23 | A | 100 | 3 | 7.0 | 37 |
| 24 | B | 98 | 1 | 8.2 | 26 |

Note that, the “amount of change” in the rinsing agent Nos. 2 to 24 is an amount of change when the rinsing agent No. 1 is used as a standard, and the “amount of change” of the rinsing agent No. 1 is determined as 0 nm.

It was confirmed from Table 2 that the disclosed rinsing agent for lithography had improvements in the effect of preventing collapse of the resist pattern, and LWR value, compared to the case where the straight-chain alkanediol (A) was not contained, the case where only a typical surfactant material was contained, and the case where the material (B-3) disclosed in JP-A No. 2012-42531 was contained. Moreover, the disclosed rinsing agent for lithography had a less change in the pattern compared to the case where only a typical surfactant material was contained, and the case where the material (B-3) disclosed in JP-A No. 2012-42531 was contained. Furthermore, it was confirmed that the disclosed rinsing agent for lithography had the improved LWR value compared to the case where only benzalkonium chloride was contained.

With regard to a type of the straight-chain alkanediol, it was confirmed that the C8 straight-chain alkanediol had a high effect of preventing collapse of the resist pattern, and a high effect of improving LWR.

With regard to an amount of the straight-chain alkanediol, a high effect of preventing collapse of the resist pattern, and a high effect of improving LWR were obtained in the case where the rinsing agent contained 0.2 parts by mass or greater of the straight-chain alkanediol relative to 100 parts by mass of the water.

Moreover, when the straight-chain alkanediol was used in combination with the surfactant, the same or similar properties were obtained to the case where the straight-chain alkanediol was used alone.

### <Evaluation of Process Flow>

An influence of a process flow after developing was determined. In the case where the following three process flows were performed, the influences thereof to an effect of preventing collapse of the resist pattern, variation in the resist pattern width, and LWR improvement rate were evaluated. The results are presented in Tables 3-1 to 3-3.

(I) alkali developing→rinsing→spin drying
(II) alkali developing→rinsing→spin drying→baking (at 110° C., for 60 sec.)
(III) alkali developing→rinsing→rinsing with pure water→spin drying

The evaluated rinsing agents for lithography were three types, the rinsing agent Nos. 1, 4 and 8 of Table 1, and the evaluation were carried out for the effect of preventing collapse of the resist pattern, amount of change in the resist pattern width, and LWR improvement rate, in the same manner to the above. Note that, the LWR improvement rates in the processes (II) and (III) was determined taking the value of LWR with the rinsing agent No. 1 in the process (I) as unprocessed.

TABLE 3-1

| | Normal process (I) | | | | |
|---|---|---|---|---|---|
| | Effect of | | | | |
| | preventing | Size after | Amount of | | LWR |
| Rinsing | collapse of | processing | change | LWR | improvement |
| agent No. | resist pattern | (nm) | (nm) | (nm) | rate (%) |
| 1 | D | 97 | — | 11.1 | — |
| 4 | A | 96 | −1 | 7.6 | 32 |
| 8 | C | 90 | −7 | 12.4 | −12 |

TABLE 3-2

| | Normal process (II) | | | | |
|---|---|---|---|---|---|
| | Effect of | | | | |
| | preventing | Size after | Amount of | | LWR |
| Rinsing | collapse of | processing | change | LWR | improvement |
| agent No. | resist pattern | (nm) | (nm) | (nm) | rate (%) |
| 1 | D | 97 | — | 11.6 | −5 |
| 4 | A | 96 | −1 | 7.5 | 32 |
| 8 | C | 88 | −9 | 12.3 | −11 |

TABLE 3-3

| | Normal process (III) | | | | |
|---|---|---|---|---|---|
| | Effect of | | | | |
| | preventing | Size after | Amount of | | LWR |
| Rinsing | collapse of | processing | change | LWR | improvement |
| agent No. | resist pattern | (nm) | (nm) | (nm) | rate (%) |
| 1 | D | 97 | — | 11.5 | −4 |
| 4 | A | 96 | −1 | 7.9 | 29 |
| 8 | D | 88 | −9 | 12.5 | −13 |

It was clear from Tables 3-1 to 3-3 that the rinsing agent for lithography No. 4 using 1,2-octanediol improved LWR both in the processes (II) and (III) compared to the process (I). With regard to the collapse of the resist pattern, there was no difference in any of the processes, and a high effect thereof could be maintained.

On the other hand, any improvement was observed with the rinsing agent for lithography No. 1 by adding the process of baking, and the process of rinsing with pure water. The rinsing agent No. 8 exhibited tinning of the resist pattern and deterioration in LWR in the process (III) where rinsing with pure water was added.

Note that, a process flow in which baking was performed after rinsing with pure water, and moreover spin drying was performed in addition to the process (II) was evaluated, but the result was the same as the result of the process (II).

### Example 2

### Formation of Resist Pattern

With reference to Example described in US Patent Application No. US2011/0159429 A1, a resist (chemically-amplified positive resist) material used for evaluation was prepared with the following formulation.

### Formulation of Resist Material

| | | |
|---|---|---|
| Resin: a resin represented by the following structural formula | 40 | parts by mass |

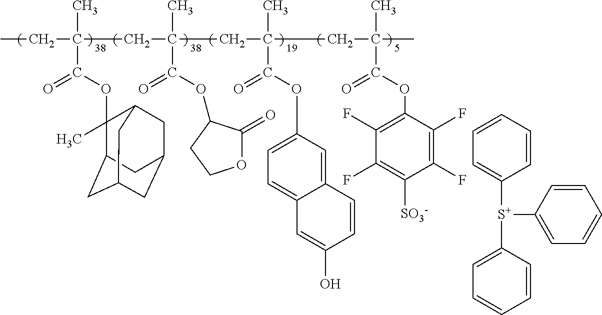

| | | |
|---|---|---|
| Additive: trioctyl amine (manufactured by Aldrich) | 0.1 | parts by mass |
| Solvent: propylene glycol monomethyl ether acetate (manufactured by | 1,100 | parts by mass |
| Kanto Chemical Co., Inc.) | | |
| Solvent: γ-butyrolactone (manufactured by Tokyo Chemical Industry | 200 | parts by mass |
| Co., Ltd.) | | |

On a silicon substrate, ARC-39 (manufactured by Nissan Chemical Industries, Ltd.) was formed as an underlayer organic film, to give a film thickness of 82 nm. Onto the film of ARC-39, the resist material above was applied by spin coating to give a film thickness of 50 nm, and the applied resist material was baked at 130° C. for 60 seconds. Subsequently, the substrate was exposed to light by means of an electron beam exposure device at the accelerated voltage of 50 keV to write a set of 101 line and space patterns (100 lines of a resist line pattern) each having a width of 24 nm. Subsequently, the resulting resist material was baked at 130° C. for 60 seconds.

Next, paddle development was performed for 30 seconds using a 2.38% by mass tetramethyl ammonium hydroxide aqueous solution (developing solution). Before the resist film was dried (in the state where the developing solution was located on the resist film), each of the rinsing agents of Table 1 was applied onto the resist film dropwise, to replace the developing solution with the rinsing agent, and then the rinsing agent was shaken off. Finally, drying was performed.

### <Evaluation of Rinsing Agent for Lithography>

Next, the resist patterns obtained through the aforementioned processes were observed under a scanning electron microscope (SEM), and were evaluated in the same manner as in Example 1. The results are presented in Table 4.

TABLE 4

| | Effect of | | | | |
|---|---|---|---|---|---|
| | preventing | Size after | Amount of | | LWR |
| Rinsing | collapse of | processing | change | LWR | improvement |
| agent No. | resist pattern | (nm) | (nm) | (nm) | rate (%) |
| 1 | D | 23 | — | 7.0 | — |
| 2 | C | 22 | −1 | 5.7 | 19 |
| 3 | C | 22 | −1 | 5.6 | 20 |
| 4 | A | 23 | 0 | 4.0 | 43 |
| 5 | A | 23 | 0 | 4.2 | 40 |
| 6 | D | 17 | −6 | 7.5 | −7 |
| 7 | D | 17 | −6 | 8.0 | −14 |
| 8 | C | 17 | −6 | 7.4 | −6 |
| 9 | B | 22 | −1 | 6.4 | 7 |
| 10 | C | 23 | 0 | 5.6 | 20 |
| 11 | B | 22 | −1 | 4.4 | 37 |
| 12 | A | 22 | −1 | 4.2 | 40 |
| 13 | A | 25 | 2 | 4.0 | 43 |
| 14 | A | 23 | 0 | 5.0 | 29 |
| 15 | A | 22 | −1 | 4.3 | 39 |
| 16 | C | 18 | −5 | 7.2 | −3 |
| 17 | B | 23 | 0 | 4.6 | 34 |
| 18 | A | 23 | 0 | 4.9 | 30 |
| 19 | A | 22 | −1 | 4.9 | 30 |
| 20 | B | 23 | 0 | 5.3 | 24 |
| 21 | B | 23 | 0 | 4.7 | 33 |
| 22 | B | 22 | −1 | 5.3 | 24 |
| 23 | A | 25 | 2 | 4.9 | 33 |
| 24 | B | 22 | −1 | 5.0 | 29 |

Note that, the “amount of change” in the rinsing agent Nos. 2 to 24 is an amount of change when the rinsing agent No. 1 is used as a standard, and the “amount of change” of the rinsing agent No. 1 is determined as 0 nm.

It was confirmed from Table 4 that the same results could be obtained to those of Table 2 even when the resist material different from that of Example 1 was used.

### Example 3

### Production of Semiconductor Device

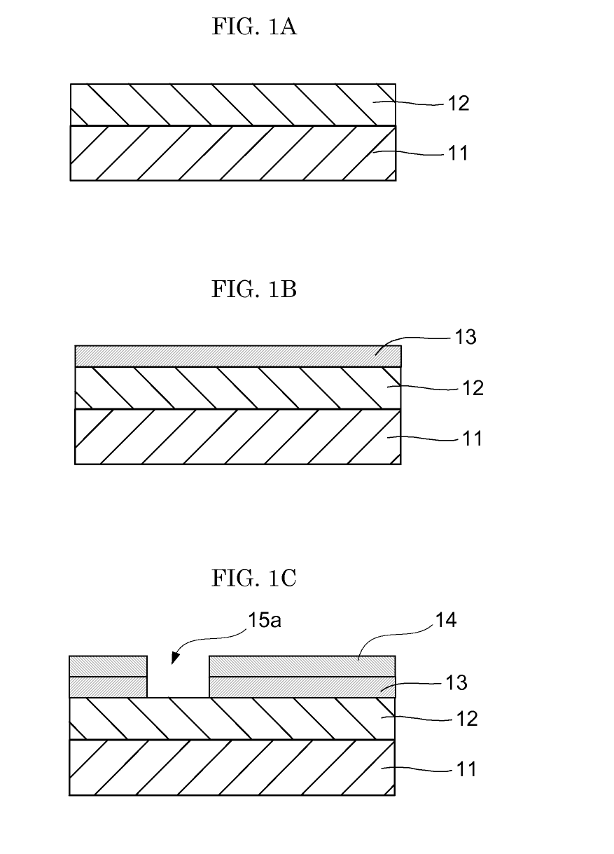

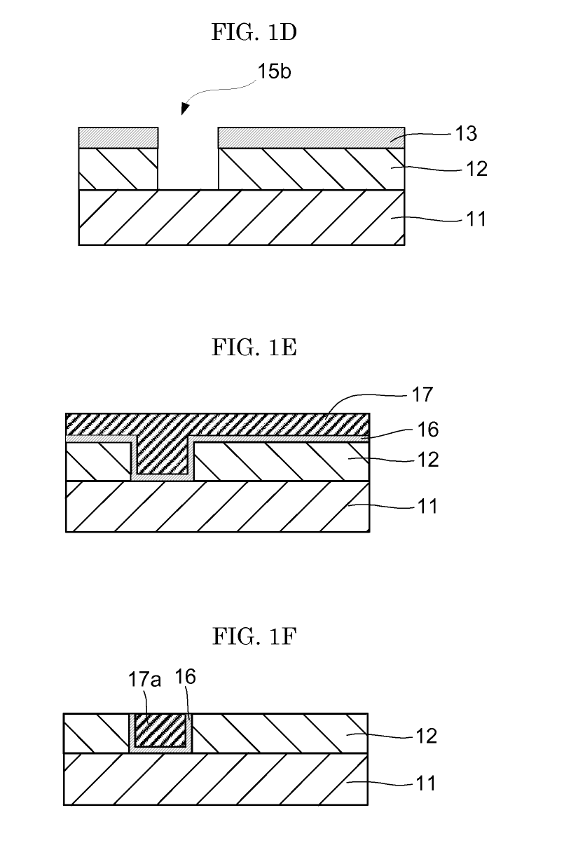

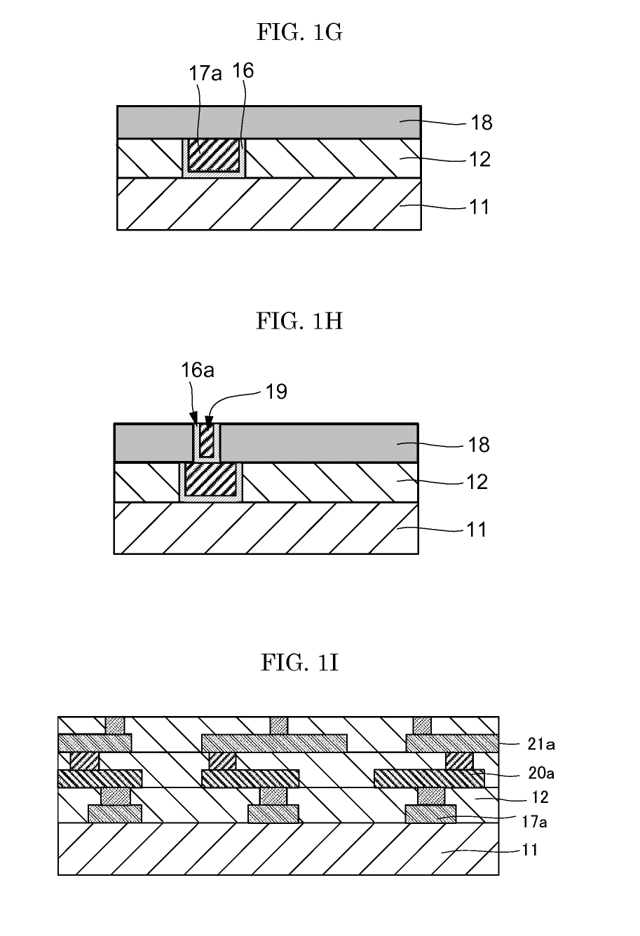

As illustrated in FIG. 1A, an interlayer insulating film 12 was formed on a silicon substrate 11. Subsequently, a titanium film 13 was formed on the interlayer insulating film 12 by sputtering, as illustrated in FIG. 1B. Next, as illustrated in FIG. 1C, a resist pattern 14 was formed by electron beam exposure, and the titanium film 13 was patterned by reactive ion etching using the formed resist pattern 14 as a mask to thereby form an opening 15a. Subsequently, reactive ion etching was performed to remove the resist pattern, as well as forming an opening 15 b in the interlayer insulating film 12 using the titanium film 13 as a mask, as illustrated in FIG. 1D.

Next, the titanium film 13 was removed by a wet treatment. As illustrated in FIG. 1E, a TiN film 16 was formed on the interlayer insulating film 12 by sputtering, and then a Cu film 17 was formed on the TiN film 16 by electroplating. Next, as illustrated in FIG. 1F, chemical mechanical polishing (CMP) was performed to flatten the laminate with remaining the barrier metal and the Cu film (first metal film) only in a recess corresponding to the opening 15b(FIG. 1D), to thereby form a first layer wire 17a.

Next, as illustrated in FIG. 1G, an interlayer insulating film 18 was formed on the first layer wire 17a. Thereafter, in the same manner as in FIGS. 1A to 1F, a Cu plug (second metal film) 19 and a TiN film 16a, which would connect the first layer wire 17a with upper layer wires formed later, were formed as illustrated in FIG. 1H.

By repeating each of the aforementioned processes, a semiconductor device having a multilayer wiring structure, which contained the first layer wire 17a, a second layer wire 20a, and a third layer wire 21a on the silicone substrate 11, was produced as illustrated in FIG. 1I. Note that, barrier metal layers each formed in the layer below the wire of each layer were not illustrated in FIG. 1I.

In Example 3, the rinsing agent for lithography No. 4 of Example 1 was used for forming the resist pattern 14.

Moreover, the interlayer insulating film 12 was a low dielectric film having a dielectric constant of 2.7 or lower. Examples of such layer include a microporous silica film (CERAMATE NCS, manufactured by JCG Catalysts and Chemicals Ltd., dielectric constant: 2.25), and a fluorocarbon film (dielectric constant: 2.4) deposited and formed with a mixed gas of C₄F₈ and C₂H₂, or a C₄F₈ gas as a source by RFCVD (power: 400 W).

The disclosed rinsing agent for lithography can be suitably used for preventing collapse of a resist pattern, which is a problem when a fine pattern is formed, and improving ununiformity of a resist pattern width, to thereby form a fine pattern extending the exposure limit.

Moreover, the disclosed rinsing agent for lithography can be suitably used for various patterning methods, and production methods of a semiconductor. The disclosed rinsing agent for lithography can be particularly preferably used for the disclosed method for forming a resist pattern, and the disclosed method for producing a semiconductor device.

The disclosed method for producing a semiconductor device can be suitably used for productions of various semiconductor devices, such as flash memory, DRAM, and FRAM.

All examples and conditional language provided herein are intended for pedagogical purposes to aid the reader in understanding the invention and the concepts contributed by the inventor to further the art, and are not to be construed limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the sprit and scope of the invention.

1. A rinsing agent for lithography, comprising:
C6-C8 straight-chain alkanediol; and
water.

2. The rinsing agent according to claim 1, wherein the C6-C8 straight-chain alkanediol is contained in an amount of 0.2 parts by mass or greater, relative to 100 parts by mass of the water.

3. The rinsing agent according to claim 1, wherein the C6-C8 straight-chain alkanediol is 1,2-hexanediol, 1,2-heptanediol, 1,2-octanediol or 1,8-octanediol or any combination thereof.

4. The rinsing agent according to claim 1, further comprising a surfactant.

5. The rinsing agent according to claim 4, wherein the surfactant is benzalkonium chloride.

6. A method for forming a resist pattern, comprising:
developing a resist film, which has been formed on a processing surface and subjected to exposing, with a developing solution; and
following the developing, rinsing the resist film with a rinsing agent for lithography,
wherein the rinsing agent for lithography contains:
C6-C8 straight-chain alkanediol; and
water.

7. The method according to claim 6, further comprising heating following the rinsing.

8. The method according to claim 6, further comprising performing second rinse with pure water after the rinsing.

9. The method according to claim 6, wherein the C6-C8 straight-chain alkanediol is contained in an amount of 0.2 parts by mass or greater, relative to 100 parts by mass of the water.

10. The method according to claim 6, wherein the C6-C8 straight-chain alkanediol is 1,2-hexanediol, 1,2-heptanediol, 1,2-octanediol or 1,8-octanediol or any combination thereof.

11. The method according to claim 6, wherein the rinsing agent further comprises a surfactant.

12. The method according to claim 11, wherein the surfactant is benzalkonium chloride.

13. A method for producing a semiconductor device, comprising:
developing a resist film, which has been formed on a processing surface and subjected to exposing, with a developing solution;
following the developing, rinsing the resist film with a rinsing agent for lithography; and
after the rinsing, etching the processing surface using the formed resist pattern as a mask to pattern the processing surface,
wherein the rinsing agent for lithography comprises:
C6-C8 straight-chain alkanediol; and
water.

14. The method according to claim 13, wherein the C6-C8 straight-chain alkanediol is contained in an amount of 0.2 parts by mass or greater, relative to 100 parts by mass of the water.

15. The method according to claim 13, wherein the C6-C8 straight-chain alkanediol is 1,2-hexanediol, 1,2-heptanediol, 1,2-octanediol or 1,8-octanediol or any combination thereof.

16. The method according to claim 13, wherein the rinsing agent further comprises a surfactant.

17. The method according to claim 16, wherein the surfactant is benzalkonium chloride.
